(19) United States
(12) Patent Application Publication
(10) Pub. No.: US 2013/0093057 A1
(43) Pub. Date: Apr. 18, 2013

(54) SEMICONDUCTOR DEVICE

(71) Applicant: Koichi YAMAOKA, Kanagawa-ken (JP)

(72) Inventor: Koichi YAMAOKA, Kanagawa-ken (JP)

(73) Assignee: Kabushiki Kaisha Toshiba, Tokyo (JP)

(21) Appl. No.: 13/601,966

(22) Filed: Aug. 31, 2012

(30) Foreign Application Priority Data
Oct. 14, 2011 (JP) P2011-226921

(51) Int. Cl. H01L 29/73

(52) U.S. Cl. 257/565; 257/E29.174

(57) ABSTRACT

A semiconductor device includes a first conductive type semiconductor layer formed on a substrate; a first conductive type embedded layer formed between the substrate and the semiconductor layer; a second conductive type well formed on the semiconductor layer; a first conductive type first contact layer that is positioned on the semiconductor layer, separate from the well; a second conductive type second contact layer formed on the well; a first conductive type third contact layer formed on the well between the first and second contact layers; and a first conductive type deep layer formed between the embedded layer and the first contact layer and in contact with the first contact layer. A minimum point in the effective impurity concentration profile along a straight line that extends in a vertical direction and passes through the embedded layer and the second part exists between the embedded layer and the first part.

### CROSS-REFERENCE TO RELATED APPLICATION

This application is based upon and claims the benefit of priority from Japanese Patent Application No. 2011-226921, filed Oct. 14, 2011; the entire contents of which are incorporated herein by reference.

### FIELD

Embodiments described herein relate to a semiconductor device.

### BACKGROUND

In semiconductor devices having bipolar transistors, a technique that has been proposed to protect against a surge current employs a protective element that short-circuits the emitter and the base of the bipolar transistor to cause the surge current to flow from the collector to the emitter-base. The protective element is required to generate a voltage (hold voltage) to some level, when the surge current flows, to consume the power of the surge current in the protective element. However, in the protective element of the emitter-base (EB) short circuit type, it is difficult to realize a high hold voltage.

### DESCRIPTION OF THE DRAWINGS

FIG. 1A to FIG. 1C illustrate cross-sections of a semiconductor device according to a first embodiment.

FIG. 2 is a graph showing the effective impurity concentration profile, where the abscissa indicates the position in the vertical direction and the ordinate indicates the effective impurity concentration.

FIG. 3 schematically illustrates the operation of a protective element in the semiconductor device of the first embodiment.

FIG. 4 is a graph showing the I-V characteristic of the protective element in the semiconductor device of the first embodiment, where the abscissa indicates the voltage, which is applied to the protective element, and the ordinate indicates the current flowing in the protective element.

FIG. 5A illustrates a cross-section of a protective element region of a semiconductor device of a first comparative example, and FIG. 5B illustrates a cross-section of a protective element region of a semiconductor device of a second comparative example.

FIG. 6 illustrates a cross-section of a protective element region of a semiconductor device according to a second embodiment.

### DETAILED DESCRIPTION

In general, the invention will be explained with reference to the figures.

A semiconductor device according to one embodiment includes a protective element of an emitter-base short circuit type having a high hold voltage. In this semiconductor device, a protective element region and a transistor region are set. The semiconductor substrate is provided with a substrate and a first conductive type semiconductor layer formed in both the protective element region and the transistor region on the substrate.

In addition, the semiconductor device is provided with a first conductive type first embedded layer that is formed between the substrate and the semiconductor layer in the protective element region and has an effective impurity concentration higher than the effective impurity concentration of the semiconductor layer, a second conductive type first well formed on the semiconductor layer in the protective element region, a first conductive type first contact layer that is positioned on the semiconductor layer, separate from the first well, and formed in an area straight above the first embedded layer, a second conductive type second contact layer formed on the first well, a first conductive type third contact layer that is positioned on the first well and formed between the first contact layer and the second contact layer, and a first conductive type first deep layer that is formed between the first embedded layer and the first contact layer and makes contact with the first contact layer.

Moreover, the semiconductor device is provided with a first conductive type second embedded layer that is formed between the substrate and the semiconductor layer in the transistor region and has an effective impurity concentration higher than the effective impurity concentration of the semiconductor layer, a second conductive type second well formed on the semiconductor layer in the transistor region, a first conductive type fourth contact layer that is positioned on the semiconductor layer in the transistor region, separate from the second well, and formed in an area straight above the second embedded layer, a second conductive type fifth contact layer formed on the second well, a first conductive type sixth contact layer that is positioned on the second well and formed between the fourth contact layer and the fifth contact layer, and a first conductive type second deep layer that is formed between the second embedded layer and the fourth contact layer and makes contact with the fourth contact layer.

Furthermore, the second contact layer is electrically connected to the third contact layer. In addition, the minimum point value between the first embedded layer and the first deep layer in the effective impurity concentration profile along a straight line, which extends in the vertical direction and passes through the first embedded layer and the first deep layer, is smaller than the minimum point value between the second embedded layer and the second deep layer in the effective impurity concentration profile along a straight line which extends in the vertical direction and passes through the second embedded layer and the second deep layer.

In the semiconductor device according to another embodiment, a protective element region and a transistor region are set. The semiconductor device is provided with a substrate and a first conductive type semiconductor layer formed in both the protective element region and the transistor region on the substrate, a first conductive type first embedded layer that is formed between the substrate and the semiconductor layer in the protective element region and has an effective impurity concentration higher than the effective impurity concentration of the semiconductor layer, a second conductive type first well formed on the semiconductor layer, a first conductive type first contact layer that is positioned on the semiconductor layer, separate from the first well, and formed in an area straight above the first embedded layer, a second conductive type second contact layer formed on the first well, a first conductive type third contact layer that is positioned on the first well and formed between the first contact layer and the second contact layer, and a first conductive type first deep layer that is formed between the first embedded layer and the first contact layer and makes contact with the first contact layer.

Moreover, the semiconductor device is provided with a first conductive type second embedded layer that is formed between the substrate and the semiconductor layer in the transistor region and has an effective impurity concentration higher than the effective impurity concentration of the semiconductor layer, a second conductive type second well formed on the semiconductor layer in the transistor region, a first conductive type fourth contact layer that is positioned on the semiconductor layer in the transistor region, separate from the second well, and formed in an area straight above the second embedded layer, a second conductive type fifth contact layer formed on the second well, and a first conductive type sixth contact layer that is positioned on the second well and formed between the fourth contact layer and the fifth contact layer.

Furthermore, the second contact layer is electrically connected to the third contact layer. In addition, the fourth contact layer makes contact with the semiconductor layer.

The semiconductor device as an embodiment is provided with a substrate, a first conductive type semiconductor layer formed on the substrate, a first conductive type embedded layer that is formed between the substrate and the semiconductor layer and has an effective impurity concentration higher than the effective impurity concentration of the semiconductor layer, a second conductive type well formed on the semiconductor layer, a first conductive type first contact layer that is positioned on the semiconductor layer, separate from the well, and formed in an area straight above the embedded layer, a second conductive type second contact layer formed on the well, a first conductive type third contact layer that is positioned on the well and formed between the first contact layer and the second contact layer, and a first conductive type first deep layer that is formed between the embedded layer and the first contact layer and makes contact with the first contact layer.

In addition, the deep layer has a first part and a second part that makes contact with the first part and is shallower than the first part. The second contact layer is electrically connected to the third contact layer. The minimum point exists between the embedded layer and the first part in an effective impurity concentration profile along a straight line which extends in the vertical direction and passes through the embedded layer and the second part.

First, a first embodiment will be explained.

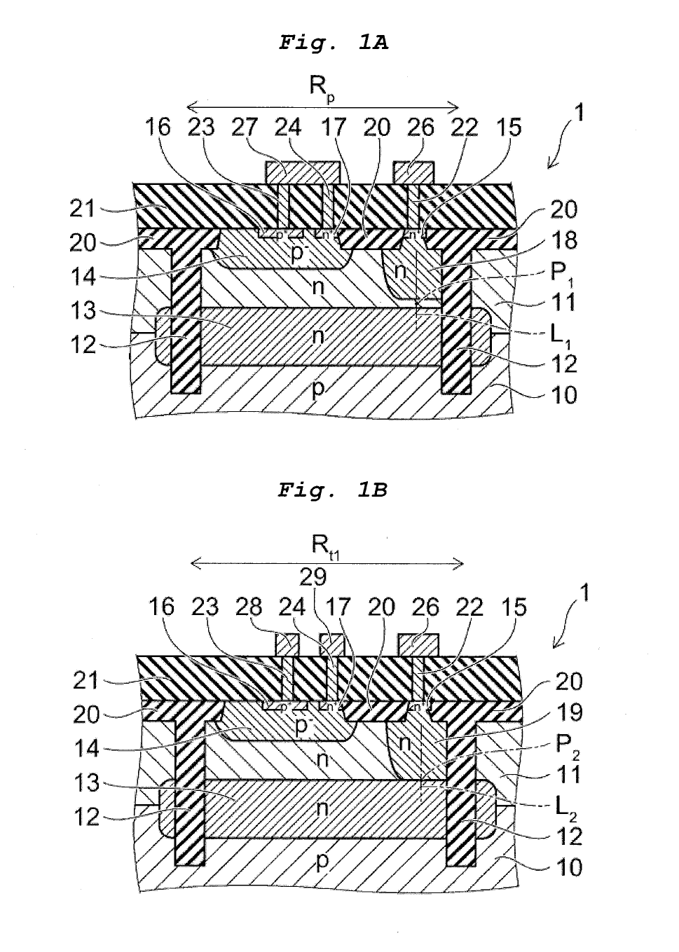

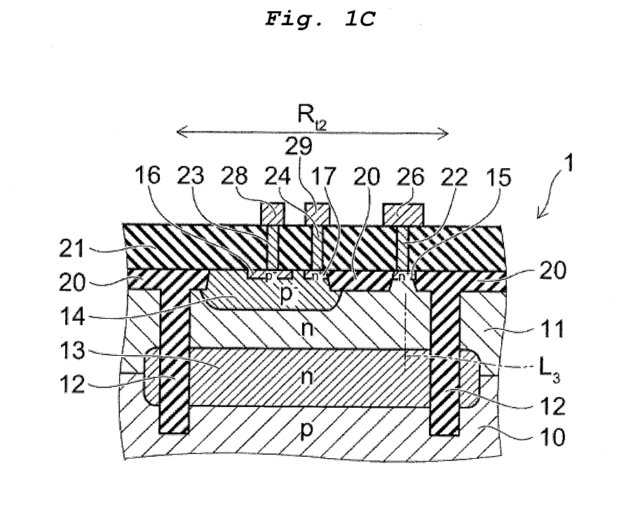

As shown in FIG. 1A to FIG. 1C, in the semiconductor device 1 of this embodiment, a protective element region Rₚ for protecting the semiconductor device 1 from a surge current such as ESD (electrostatic discharge) and transistor regions Rₜ₁ and Rₜ₂ where bipolar transistors are formed are set.

FIG. 1A shows the protective element region Rₚ; FIG. 1B shows the transistor region Rₜ₁; and FIG. 1C shows the transistor region Rₜ₂.

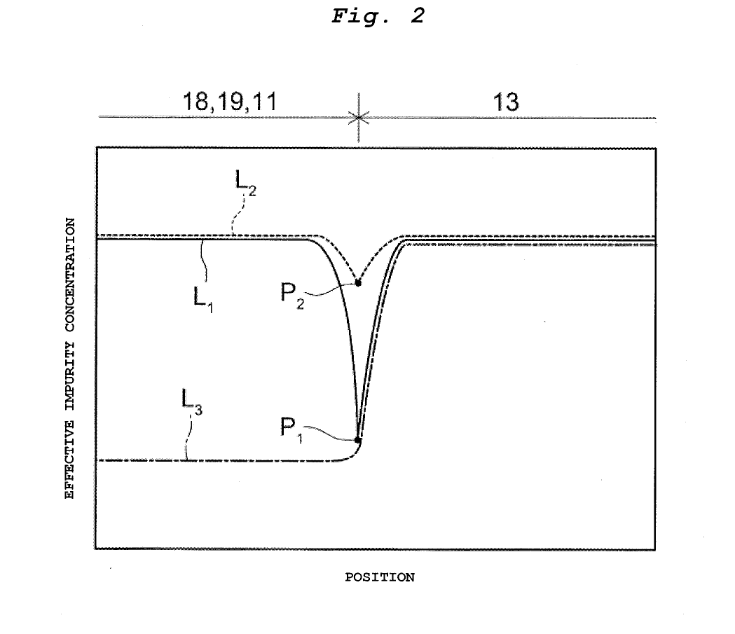

FIG. 2 shows the effective impurity concentration profile along straight lines L₁, L₂, and L₃ shown in FIG. 1A, FIG. 1B, and FIG. 1C, respectively.

As described herein, “effective impurity concentration” means the concentration of impurities contributing to the conduction of a semiconductor material. For example, in case both impurities as a donor and impurities as an acceptor are included in the semiconductor material, the concentration after excluding the canceled portion of the donor and the acceptor is the effective impurity concentration.

As shown in FIG. 1A to FIG. 1C, a p type silicon substrate 10 whose conductive type is the p type is formed in the semiconductor device 1. On the entire surface of the p type silicon substrate 10, an n type epitaxial layer 11 whose conductive type is then type is formed as a semiconductor layer. In the n type epitaxial layer 11, silicon containing a donor is formed on the upper surface of the p type silicon substrate by epitaxial growth. In addition, DTI (deep trench isolation: deep groove element isolator) 12 composed of an insulating material such as silicon oxide is formed in a frame shape when from the top view, so that it reaches the upper part of the p type silicon substrate 10 through the n type epitaxial layer 11. The region enclosed by the DTI 12 is the protective element region Rₚ and the transistor regions Rₜ₁ and Rₜ₂. The p type silicon substrate 10 and the n type epitaxial layer 11 are commonly formed in the protective element region Rₚ and the transistor regions Rₜ₁ and Rₜ₂.

Next, a configuration common to the protective element region Rₚ and the transistor regions Rₜ₁ and Rₜ₂ (hereinafter, also referred to “each region”) will be explained.

As shown in FIG. 1A to FIG. 1C, in the protective element region Rₚ and the transistor regions Rₜ₁ and Rₜ₂, an n type embedded layer 13 is formed between the p type silicon substrate 10 and the n type epitaxial layer 11. The conductive type of the n type embedded layer 13 is the n type, and its effective impurity concentration is higher than the effective impurity concentration of the n type epitaxial layer 11.

The n type embedded layer 13 is formed by both the upper part of the p type silicon substrate 10 and the lower part of the n type epitaxial layer 11 through the introduction of impurities as a donor into the upper part of the p type silicon substrate 10 and the lower part of the n type epitaxial layer 11. The n type embedded layer 13 is formed in entirely in a region enclosed by the DTI 12, and its end protrudes to the outside of the region enclosed by the DTI 12.

In addition, in each region, a p− type well 14 whose conductive type is the p type is respectively formed on the n type epitaxial layer 11. The p− type well 14 is formed in part of each region. In each region, the p− type well 14 is separated from the n type embedded layer 13, and the n type epitaxial layer 11 is interposed between the p− type well 14 and the n type embedded layer 13. The p− type well 14 is formed by selectively introducing impurities as an acceptor into the upper part of the n type epitaxial layer 11.

Moreover, n+ type collector layer 15, p+ type base layer 16, and n+ type emitter layer 17 are formed as contact layers in each region. The n+ type collector layer 15 is positioned on the n type epitaxial layer 11, separate from the p− type well 14, and formed at a position in an area straight above the n type embedded layer 13. The conductive type of the n+ type collector layer 15 is the n type, and its effective impurity concentration is higher than the effective impurity concentration of the n type epitaxial layer 11. The p+ type base layer 16 is formed on the p− type well 14. The conductive type of the p+ type base layer 16 is the p type, and its effective impurity concentration is higher than the effective impurity concentration of the p− type well 14. The n+ type emitter layer 17 is positioned on the p− type well 14 and formed between the n+ type collector layer 15 and the p+ type base layer 16. The conductive type of the n+ type emitter layer 17 is the n type, and its effective impurity concentration is higher than the effective impurity concentration of the n type epitaxial layer 11. On the surfaces of the n+ type collector layer 15, p+ type base layer 16, and n+ type emitter layer 17, silicide layers (not shown in the figure) are formed.

Between the n+ type collector layer 15 and the n+ type emitter layer 17 on the n type epitaxial layer 11, STI (shallow trench isolation: shallow groove element isolator) 20 is installed. The lower surface of the STI 20 is positioned lower than each lower surface of the n+ type collector layer 15, p+ type base layer 16, and n+ type emitter layer 17, and higher than the lower surface of the p− type well 14.

Above the n type epitaxial layer 11, DTI 12, and STI 20, an interlayer dielectric 21 is formed over the entire surface. A collector contact 22 is formed in an area right on the n+ type collector layer 15 in the interlayer dielectric 21 and connected to the n+ type collector layer 15. A base contact 23 is formed in an area right on the p+ type base layer 16 in the interlayer dielectric 21 and connected to the p+ type baser layer 16. An emitter contact 24 is formed in an area right on the n+ type emitter layer 17 in the interlayer dielectric 21 and connected to the n+ type emitter layer 17. The collector contact 22, base contact 23, and emitter contact 24 have a pillar shape extending in the vertical direction and are formed of a metal.

Next, different configurations of the protective element region Rₚ and the transistor regions Rₜ₁ and Rₜ₂ will be explained.

As shown in FIG. 1A, in the protective element region Rₚ, a deep n type layer 18 is formed between the n type embedded layer 13 and the n+ type collector layer 15. The conductive type of the deep n type layer 18 is the n type, and its effective impurity concentration is higher than the effective impurity concentration of the n type epitaxial layer 11 and is about the same as the effective impurity concentration of the n type embedded layer 13, and is lower than the effective impurity concentration of the n+ type collector layer 15. The deep n type layer 18 makes contact with the n+ type collector layer 15 and does not make contact with the n type embedded layer 13. In other words, the n type epitaxial layer 11 is interposed between the deep n type layer 18 and the n type embedded layer 13.

In addition, a collector electrode 26 and an emitter-base electrode 27 are formed on the interlayer dielectric 21. The collector electrode 26 is connected to the collector contact 22, and the emitter-base electrode 27 is commonly connected to the base contact 23 and the emitter contact 24. Therefore, in the protective element region Rₚ, the p+ type base layer 16 is electrically connected to the n+ type emitter layer 17 via the base contact 23, emitter-base electrode 27, and emitter contact 24.

As shown in FIG. 1B, in the transistor region Rₜ₁, a deep n type layer 19 is formed between the n type embedded layer 13 and the n+ collector layer 15. The conductive type of the deep n type layer 19 is the n type, and its effective impurity concentration is higher than the effective impurity concentration of the n type epitaxial layer 11 and is about the same as the effective impurity concentration of the n type embedded layer 13, and is lower than the effective impurity concentration of the n+ type collector layer 15. The deep n type layer 19 makes contact with the n+ type collector layer 15 and also makes contact with the n type embedded layer 13.

As shown in FIG. 1C, in the transistor region Rₜ₂, no deep n type layer is formed between the n type embedded layer 13 and the n+ collector layer 15. For this reason, the n+ type collector layer 15 makes contact with the n type epitaxial layer 11.

In addition, as shown in FIG. 1B and FIG. 1C, in each of the transistor regions Rₜ₁ and Rₜ₂, collector electrode 26, base electrode 28, and emitter electrode 29 are formed on the interlayer dielectric 21. The collector electrode 26 is connected to the collector contact 22, the base electrode 28 is connected to the base contact 23, and the emitter electrode 29 is connected to the emitter contact 24. Therefore, in the transistor regions Rₜ₁ and Rₜ₂, the p+ type base layer 16 and the n+ type emitter layer 17 are not electrically connected, and a potential can be concurrently and independently applied to the n+ type emitter layer 15, p+ type base layer 16, and n+ type emitter layer 17.

Next, as shown in FIG. 1A to FIG. 1C and FIG. 2, in the protective element region Rₚ, the minimum point P₁ exists between the n type embedded layer 13 and the deep n type layer 18 in the effective impurity concentration profile along a straight line L₁ that extends in the vertical direction and passes through the n type embedded layer 13 and the deep n type layer 18. In addition, in the transistor region Rₜ₁, the minimum point P₂ exists between the n type embedded layer 13 and the deep n type layer 19 in the effective impurity concentration profile along a straight line L₂ that extends in the vertical direction and passes through the n type embedded layer 13 and the deep n type layer 19. Moreover, the value of the minimum point P₁ is smaller than the value of the minimum point P₂. Furthermore, the value of the minimum point P₁ is about the same as that of the effective impurity concentration of the n type epitaxial layer 11 shown by a line L₃ at the transistor region Rₜ₃. For example, the effective impurity concentration at the minimum point P₁ is 1-50 times the effective impurity concentration of the n type epitaxial layer 11.

Next, the operation of the semiconductor device of this embodiment will be explained.

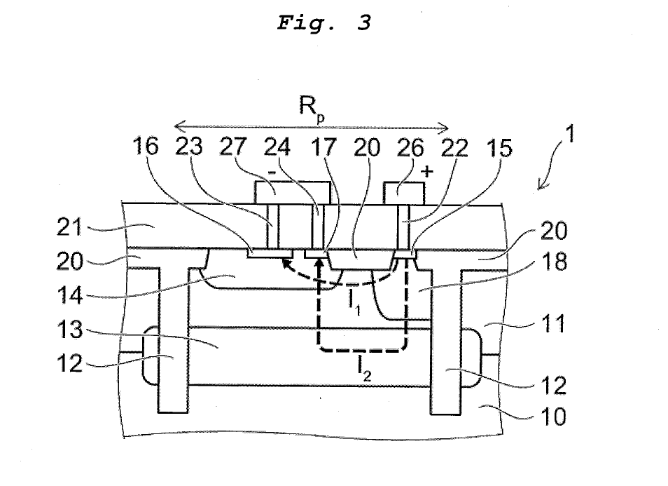

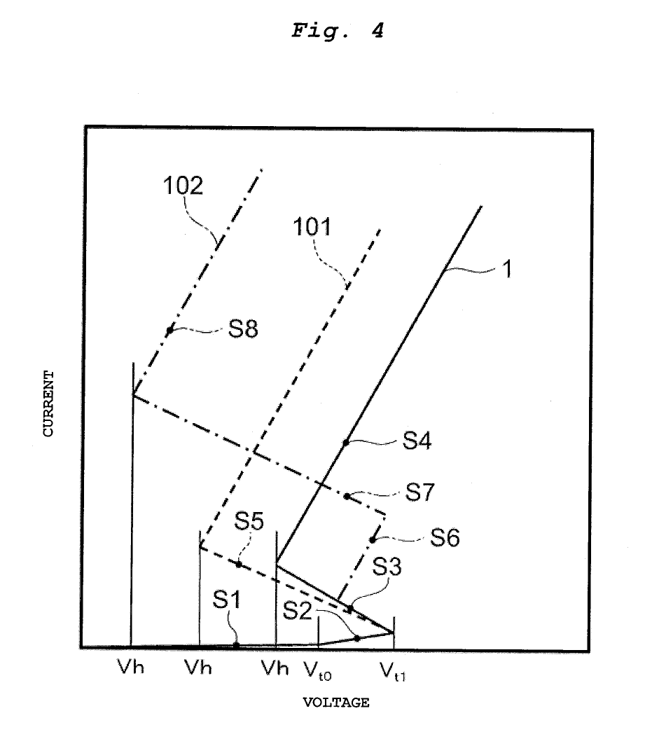

FIG. 3 is the same cross section as FIG. 1A and shows a surge current flowing in the semiconductor device 1 by an arrow.

FIG. 4 shows the behavior of a protective element formed in the protective element region Rₚ. The solid line indicates the semiconductor device 1 of this embodiment, the broken line indicates a semiconductor device 101 of a first comparative example which will be mentioned later, and the alternating long and short dash line indicates a semiconductor device 102 of a second comparative example which will be mentioned later.

As shown in FIG. 3, a surge voltage in which the collector electrode 26 is a positive electrode and the emitter-base electrode 27 is a negative electrode is applied between the collector electrode 26 and the emitter-base electrode 27 of the protective element region Rₚ. The surge current, for example, is an ESD current. At that time, the interface between the p− type well 14 and the n type epitaxial layer 11 is a pn interface between the collector electrode 26 and the emitter-base electrode 27, and a backward voltage is applied to the pn interface. For this reason, as shown in the state S1 of FIG. 4, if the surge voltage is lower than the breakdown voltage Vto of the pn interface, no current flows.

If the surge voltage exceeds the voltage Vto, as shown in the state S2 of FIG. 3 and as shown in FIG. 4, a breakdown current I₁ flows to the p+ type base layer 16 from the n+ type collector layer 15. If the breakdown current I₁ flows, the voltage breakdown is caused along the path of the breakdown current I₁ by the resistance of the p− type well 14, and the potential of the part that makes contact with the n+ type emitter layer 17 in the p− type well 14 is higher than the potential of the n+ type emitter layer 17. Therefore, a forward voltage is applied to the pn interface between the p− type well 14 and the n+ type emitter layer 17, starting the conducting path of an npn bipolar transistor between the n+ type collector layer 15 and the n+ type emitter layer 17. As a result, a bipolar current I₂ flows to the n+ type emitter layer 17 from the n+ type collector layer 15. At that time, the bipolar current I₂ passes through the n+ type collector layer 15, deep n type layer 18, n type embedded layer 13, n type epitaxial layer 11, p− type well 14, and n+ type emitter layer 17. In addition, as shown in the state S3 of FIG. 4, the voltage between the collector electrode 26 and the emitter-base electrode 27 is lowered from the turn-on voltage Vₜ₁ of the npn bipolar transistor.

Next, if the npn bipolar transistor between the n+ collector layer 15 and the n+ type emitter layer 17 is in a completely conductive state, the resistance is almost constant, and as shown in the state S4 of FIG. 4, the voltage also rises with the increase in current. At that time, the bipolar current I₂ is larger than the breakdown current I₁. As a result, the current flowing in the n type embedded layer 13 is larger than the current flowing in the n type epitaxial layer 11 without passing through the n type embedded layer 13. For example, about 98% of the entire surge current flows in the n type embedded layer 13. Next, when the state transits from the state S3 to the state S4, the voltage between the collector electrode 26 and the emitter-base electrode 27 is the minimum value, but the minimum value becomes the hold voltage Vh.

On the other hand, an npn transistor is formed in the transistor regions Rₜ₁ and Rₜ₂ and functions as an ordinary circuit element.

Next, the effect of this embodiment will be explained.

In this embodiment, in the protective element region Rₚ, since the deep n type layer 18 is formed between the n+ type collector layer 15 and the n type embedded layer 13, the bipolar current I₂ can be reliably introduced into the n type embedded layer 13. Next, the bipolar current I₂ introduced into the n type embedded layer 13 flows to the n+ type emitter layer 17 via the n type epitaxial layer 11 and the p− type well 14. Therefore, since the current path of the bipolar current I₂ can be regulated by the existence of the deep n type layer 18, even if there is an increase in the surge current, the hold voltage Vh is not excessively lowered.

In addition, in the protective element region Rₚ, since the deep n type layer 18 and the n type embedded layer 13 are separated and the n type epitaxial layer 11 is interposed between them, a resistance to some degree can be realized in the current path of the bipolar current I₂. Therefore, the proper hold voltage Vh can be secured.

Therefore, in the semiconductor device of this embodiment, since the surge current flows while the proper hold voltage Vh in the protective element region Rₚ is maintained, the power of the surge current is consumed in the protective element region Rₚ, and circuits can be effectively protected. Here, the circuits to be protected may include the npn bipolar transistor formed in the transistor regions Rₜ₁ and Rₜ₂.

Moreover, according to this embodiment, the protective element is formed in the protective element region Rₚ to have approximately the same configuration as the npn bipolar transistor which is formed in the transistor regions Rₜ₁ and Rₜ₂. Therefore, the protective element can be formed by the same process used for the npn bipolar transistor, thus reducing the cost of forming the protective element.

Next, comparative examples of this embodiment will be explained.

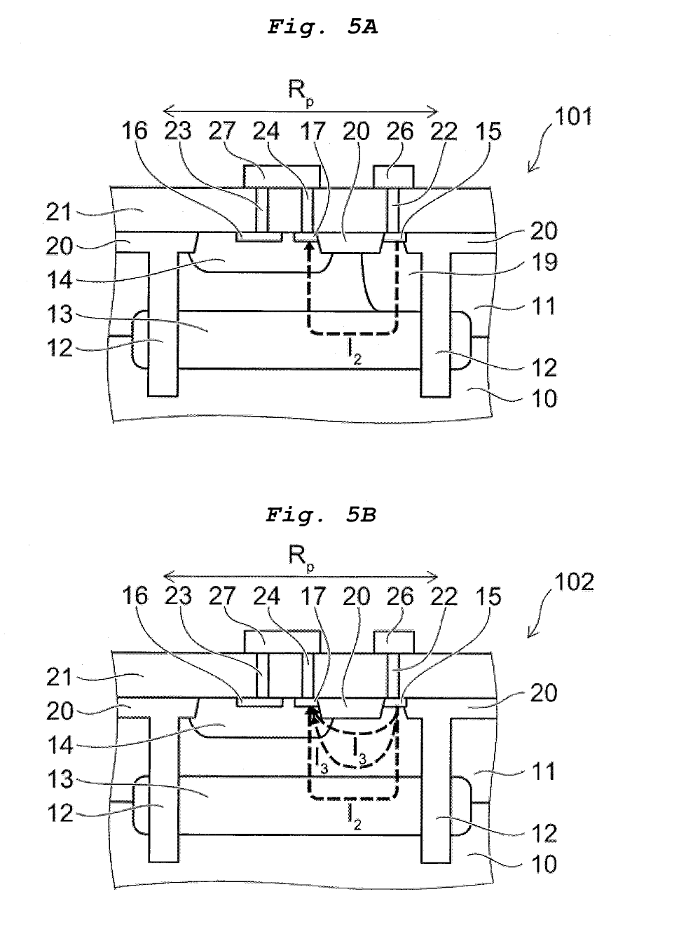

FIG. 5A is a cross section of a protective element region of a semiconductor device of a first comparative example, and FIG. 5B is a cross section of a protective element region of a semiconductor device of a second comparative example.

First, the first comparative example will be explained.

As shown in FIG. 5A, a semiconductor device 101 of the first comparative example has a configuration similar to the configuration of the npn bipolar transistor shown in FIG. 1B. In other words, in the protective element region Rₚ, the deep n type layer 19 is formed between the n+ type collector layer 15 and the n type embedded layer 13. The deep n type layer 19 makes contact with both the n+ type collector layer 15 and the n type embedded layer 13.

In the semiconductor device 101 of the first comparative example, the bipolar current I₂ flows in the path of n+ type collector layer 15 the deep n type layer 19, n type embedded layer 13, n type epitaxial layer 11, p− type well 14, and n+ type emitter layer 17, and because the deep n type layer 19 makes contact with the n type embedded layer 13, the resistance of this current path is low. For this reason, as shown in FIG. 4 for state S5 by a broken line, the voltage lowers after the npn bipolar transistor is in the conductive state, and as a result, the hold voltage Vh is lowered.

Next, the second comparative example will be explained.

As shown in FIG. 5B, a semiconductor device 102 of the second comparative example has a configuration that is similar to the configuration of the npn bipolar transistor shown in FIG. 1C. In other words, in the protective element region Rₚ, no deep n type layer is formed between the n+ type collector layer 15 and the n type embedded layer 13.

In the semiconductor device 102 of the second comparative example, since no deep n type layer is installed, the action to regulate the current path of the bipolar current I₂ to a path passing through the n type embedded layer 13 is weak. For this reason, as represented by state S6 in FIG. 4, after the npn bipolar transistor is in a completely conductive state, the bipolar current I₃ that flows in the n type epitaxial layer 11 without passing through the n type embedded layer 13 increases. The bipolar current I₃ flows in a wide path in the n type epitaxial layer 11 as shown in the cross section of FIG. 5B. Here, in FIG. 5B, the path of the bipolar current I₃ is representatively shown by two arrows. As a result, as shown in FIG. 4 for state S7, the voltage between the collector electrode 26 and the emitter-base electrode 27 starts to decrease. In one example, about a half of the entire surge current shortcuts the inside of the n type epitaxial layer 11 without passing through the n type embedded layer 13. Thereafter, if the current distribution in the n type embedded layer 13 and the n type epitaxial layer 11 is stable, as shown in FIG. 4 for state S8, the voltage rises with an increase in the current. As shown by an alternating long and short dash line in FIG. 4, the hold voltage Vh of the protective element that exhibits this behavior is lowered.

Next, a second embodiment will be explained.

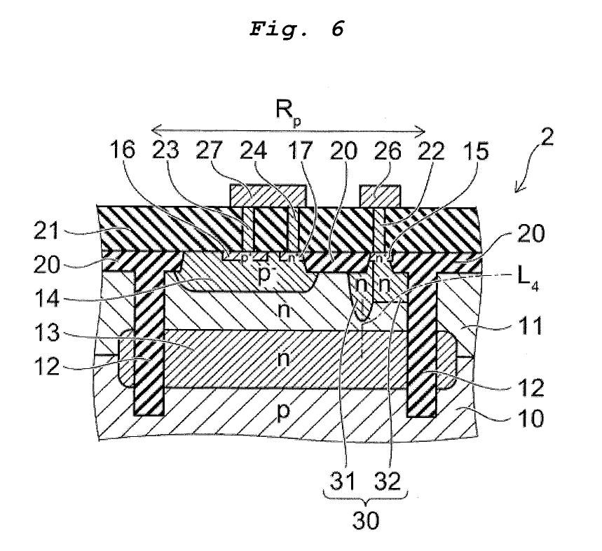

FIG. 6 is a cross section showing the protective element region of the semiconductor device of the second embodiment.

As shown in FIG. 6, the difference between the semiconductor device 2 of this embodiment and the semiconductor device 1 (see FIG. 1) of the first embodiment is that a deep n type layer 30 is formed instead of the deep n type layer 18 (see FIG. 1) in the protective element region Rₚ.

In the deep n type layer 30, parts 31 and 32 are formed. The parts 31 and 32 are arranged along the horizontal direction and makes contact with each other. The part 31 is deeper than the part 32, and the effective impurity concentration in the part 31 is higher than the effective impurity concentration in the part 32. However, the part 31 does not makes contact with the n type embedded layer 13, and the n type epitaxial layer 11 is interposed between the part 31 and the n type embedded layer 13. In other words, similarly to the minimum point P₁ shown in FIG. 2, a minimum point exists between the n type embedded layer 13 and the part 31 in the effective impurity concentration profile along a straight line L₄ that extends in the vertical direction and passes through the n type embedded layer 13 and the part 31. The value of the minimum point is about the same as the effective impurity concentration in the n type epitaxial layer 11, for example, 1-50 times. On the other hand, the depth of the part 32, for example, is one-half or more of the depth of the n type epitaxial layer 11. In addition, from a top view, for example, the area of the part 31 is smaller than the area of the part 32, for example, 50% or less. Moreover, from the top view, the parts 31 and 32 are asymmetrically arranged with respect to the n+ type collector layer 15.

The deep n type layer 30, for example, can be formed by the following method.

In other words, the parts 31 and 32 can be formed by ion-implanting impurities that are ion-implanted at different acceleration voltages, using separate masks. In this case, the acceleration voltage of the ion implantation for forming the part 31 is higher than the acceleration voltage of the ion implantation for forming the part 32.

Alternatively, using one sheet of mask in which the coating rate of a part corresponding to the part 31 is relatively low and the coating rate of a part corresponding to the part 32 is relatively high, impurities may be ion-implanted. In this case, the dosage of the impurities, which are implanted into an area corresponding to the part 31 in the n type epitaxial layer 11, is larger than the dosage of the impurities which are implanted into an area corresponding to the part 32. Next, the impurities implanted are diffused by a heat treatment. At that time, in the part 31, the impurities are diffused deeper than the part 32, forming the relatively deep part 31 and the relatively shallow part 32.

Also donor impurities can be ion-implanted into areas corresponding to the parts 31 and 32 in the n type epitaxial layer 11 to form an impurity-implanted part up to a depth corresponding to the part 31, and acceptor impurities are ion-implanted into a part corresponding to the area right under the part 32 in the impurity-implanted part. Therefore, the effective impurity concentration is lowered in the part corresponding to the area right under the part 32 by the impurities cancelling each other out. As a result, the parts 31 and 32 are formed.

Next, the operation of this embodiment will be explained.

In this embodiment, similarly to the first embodiment, when a surge voltage is applied between the collector electrode 26 and the emitter-base electrode 27, the breakdown current I₁ (see FIG. 1) of the pn diode first flows between the n+ type collector layer 15 and the p+ type base layer 16, so that the npn bipolar transistor is set to a conductive state. As a result, the bipolar current I₂ (see FIG. 1) flows between the n+ type collector layer 15 and the n+ type emitter layer 17. In the deep n type layer 30, the bipolar current I₂ flows mainly in the part 31. At a time when the entire surge current flows, the current flowing in the n type embedded layer 13 is larger than the current that flows in the n type epitaxial layer 11 without passing through the n type embedded layer 13.

Next, the effects of the second embodiment will be explained.

In the second embodiment, with the configuration of the deep n type layer 30 formed by the relatively deep part 31 and the relatively shallow part 32, the controllability of the ion implantation for forming the deep n type layer 30 can be improved. Other configurations, operations, and effects in this embodiment are similar to those of the first embodiment.

Here, in the second embodiment, several pieces for each of the parts 31 and 32 may also be formed. In addition, the relative position relation between the parts 31 and 32 is not limited to that shown in FIG. 2.

In addition, in the first and second embodiments, examples of EB short circuit type protective element with an npn structure, an npn bipolar transistor having a deep layer, and an npn transistor having no deep layer formed have been shown. However, there are additional examples; only the protective element and the npn bipolar transistor having a deep layer may be formed; or only the npn bipolar transistor having no protective element and deep layer may be formed; or the protective element and other kinds of circuits to be protected may be formed; or the protective element may be formed alone.

According to the embodiments explained above, semiconductor devices in which an emitter-base short circuit type of protective element with a high hold voltage is formed can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A protective element for a semiconductor device comprising:
a substrate;
a semiconductor layer of a first conductive type formed on the substrate;
an embedded layer of the first conductive type that is formed between the substrate and the semiconductor layer and has an effective impurity concentration higher than an effective impurity concentration of the semiconductor layer;
a well of a second conductive type formed on the semiconductor layer;
a first contact layer of the first conductive type that is positioned on the semiconductor layer, separate from the well;
a second contact layer of the second conductive type formed on the well;
a third contact layer of the first conductive type that is positioned on the well and formed between the first contact layer and the second contact layer; and
a deep layer of the first conductive type that is formed between the embedded layer and the first contact layer and makes contact with the first contact layer,
wherein the semiconductor layer is interposed between the embedded layer and the deep layer, and the deep layer is closer to the embedded layer than the well.

2. The semiconductor device according to claim 1, further comprising an insulating material formed in a deep trench that extends through the semiconductor layer and the embedded layer and reaches the substrate, and surrounding the first, second, and third contact layers, the well, and the deep layer, wherein the embedded layer is formed entirely in a region enclosed by the insulating material.

3. The semiconductor device according to claim 1, wherein when a surge current is applied between the first contact layer and the third contact layer, the current flowing in the embedded layer is larger than the current that flows in the semiconductor layer without passing through the embedded layer.

4. The semiconductor device according to claim 1, wherein the deep layer includes first and second parts that are in contact with each other.

5. The semiconductor device according to claim 4, wherein the first part is closer to the embedded layer than the second part, and the first part has an effective impurity concentration that is higher than the second part.

6. The semiconductor device according to claim 5, wherein the second part is in contact with the insulating material.

7. The semiconductor device according to claim 1, wherein the second contact layer is electrically connected to the third contact layer.

8. A semiconductor device having a protective element region and a transistor region, the semiconductor device comprising:
a substrate;
a semiconductor layer of a first conductive type formed on the substrate in both the protective element region and the transistor region;
a first embedded layer of the first conductive type that is formed between the substrate and the semiconductor layer in the protective element region and has an effective impurity concentration higher than an effective impurity concentration of the semiconductor layer;
a first well of a second conductive type formed on the semiconductor layer in the protective element region;
a first contact layer of the first conductive type that is positioned on the semiconductor layer in the protective element region, separate from the first well;
a second contact layer of the second conductive type formed on the first well;
a third contact layer of the first conductive type that is positioned on the first well and formed between the first contact layer and the second contact layer;
a first deep layer of the first conductive type that is formed between the first embedded layer and the first contact layer and makes contact with the first contact layer;
a second embedded layer of the first conductive type that is formed between the substrate and the semiconductor layer in the transistor region and has an effective impurity concentration higher than the effective impurity concentration of the semiconductor layer;
a second well of the second conductive type formed on the semiconductor layer in the transistor region;
a fourth contact layer of the first conductive type that is positioned on the semiconductor layer in the transistor region, separate from the second well, and formed in an area right on the second embedded layer;
a fifth contact layer of the second conductive type formed on the second well; and
a sixth contact layer of the first conductive type that is positioned on the second well and formed between the fourth contact layer and the fifth contact layer,
wherein the semiconductor layer is interposed between the first embedded layer and the first deep layer, and the first deep layer is closer to the first embedded layer than the first well

9. The semiconductor device according to claim 8, wherein when a surge current is applied between the first contact layer and the third contact layer, the current flowing in the first embedded layer is larger than the current flowing in the semiconductor layer without passing through the first embedded layer.

10. The semiconductor device according to claim 8, wherein the fourth contact layer makes contact with the semiconductor layer.

11. The semiconductor device according to claim 8, further comprising a second deep layer of the first conductive type that is formed between the second embedded layer and the fourth contact layer, and makes contact with the fourth contact layer and the second embedded layer.

12. The semiconductor device according to claim 11, wherein a minimum point between the first embedded layer and the first deep layer in the effective impurity concentration profile along a straight line that extends in a vertical direction and passes through the first embedded layer and the first deep layer, is smaller than a minimum point between the second embedded layer and the second deep layer in the effective impurity concentration profile along a straight line that extends in the vertical direction and passes through the second embedded layer and the second deep layer.

13. The semiconductor device according to claim 8, wherein
the first deep layer includes first and second parts that are in contact with each other.

14. The semiconductor device according to claim 13, wherein the first part is closer to the first embedded layer than the second part, and the first part has an effective impurity concentration that is higher than the second part.

15. The semiconductor device according to claim 8, further comprising an insulating material formed in a deep trench that extends through the semiconductor layer and the first embedded layer and reaches the substrate, and surrounding the first, second, and third contact layers, the first well, and the first deep layer, wherein the first embedded layer is formed entirely in a region enclosed by the insulating material.

16. The semiconductor device according to claim 8, wherein
the minimum point between the first embedded layer and the first deep layer in the effective impurity concentration profile along a straight line that extends in the vertical direction and passes through the first embedded layer and the first deep layer is about the same as the effective impurity concentration of the semiconductor layer.

17. A semiconductor device, comprising:
a substrate;
a first conductive type semiconductor layer formed on the substrate;
a first conductive type embedded layer that is formed between the substrate and the semiconductor layer and has an effective impurity concentration higher than an effective impurity concentration of the semiconductor layer;
a second conductive type well formed on the semiconductor layer;
a first conductive type first contact layer that is positioned on the semiconductor layer, separate from the well;
a second conductive type second contact layer formed on the well;
a first conductive type third contact layer that is positioned on the well and formed between the first contact layer and the second contact layer; and
a first conductive type deep layer that is formed between the embedded layer and the first contact layer and makes contact with the first contact layer, wherein
the deep layer includes a first part and a second part, the first part making contact with the second part and being closer to the embedded layer than the second part.

18. The semiconductor device according to claim 17, wherein the semiconductor layer is interposed between the embedded layer and the deep layer, and the deep layer is closer to the embedded layer than the well.

19. The semiconductor device according to claim 18, wherein the first part has an effective impurity concentration that is higher than the second part.

20. The semiconductor device according to claim 17, further comprising an insulating material formed in a trench that extends through the semiconductor layer and the embedded layer and reaches the substrate, and surrounding the first, second, and third contact layers, the well, and the deep layer, wherein the embedded layer is formed entirely in a region enclosed by the insulating material.
